(19) United States
(12) Patent Application Publication
(10) Pub. No.: US 2025/0073916 A1
(43) Pub. Date: Mar. 6, 2025

(54) MAINTENANCE DEVICE

(71) Applicant: Tokyo Electron Limited, Tokyo (JP)

(72) Inventor: Norihiko AMIKURA, Miyagi (JP)

(73) Assignee: Tokyo Electron Limited, Tokyo (JP)

(21) Appl. No.: 18/949,966

(22) Filed: Nov. 15, 2024

Related U.S. Application Data
(63) Continuation of application No. PCT/JP2023/018867, filed on May 22, 2023.

(30) Foreign Application Priority Data
May 23, 2022 (JP) 2022-083494

(51) Int. Cl. B25J 11/00; B25J 9/00

(52) U.S. Cl. CPC B25J 11/0095; B25J 9/0009

(57) ABSTRACT

Provided is a maintenance device for assisting an exchange of a transfer robot mounted on a transfer module, the maintenance device comprising: a carriage; a housing having an upper opening and a lower opening, wherein the housing is disposed above the carriage; a first lifting unit mounted on the carriage and configured to raise and lower the housing between a first upper position and a first lower position, wherein the housing is connected to the transfer module when the housing is at the first upper position; a lower shutter configured to open and close the lower opening; a support unit configured to support the transfer robot; and a second lifting unit configured to raise and lower the support unit between a second upper position within the housing and a second lower position below the housing when the housing is at the first upper position.

### CROSS-REFERENCE TO RELATED APPLICATIONS

This application is a bypass continuation application of International Application No. PCT/JP2023/018867 having an international filing date of May 22, 2023, and designating the United States, the International Application being based upon and claiming the benefit of priority from the Japanese Patent Application No. 2022-083494 filed on May 23, 2022, the entire contents of each are incorporated herein by reference.

### TECHNICAL FIELD

Various aspects and embodiments of the present disclosure relate to a maintenance device.

### BACKGROUND

Japanese Laid-open Patent Publication No. 2013-56393 discloses that, when installing a robot in a vacuum chamber that performs workpiece transfer, an upper cover of the vacuum chamber is opened to perform the transfer.

### SUMMARY

The present disclosure provides a maintenance device capable of suppressing a decrease in throughput entailed in the maintenance of parts within a transfer module.

A maintenance device in one aspect of the present disclosure, which assists the exchange of a transfer robot mounted on a transfer module, includes a carriage, a housing, a first lifting unit, a lower shutter, a support unit, and a second lifting unit. The housing has an upper opening and a lower opening and is disposed above the carriage. The first lifting unit is mounted on the carriage and is configured to raise and lower the housing between a first upper position and a first lower position. The housing is connected to a transfer module when it is at the first upper position. The lower shutter is configured to open and close the lower opening. The support unit is configured to support the transfer robot. The second lifting unit is configured to raise and lower the support unit between a second upper position within the housing and a second lower position below the housing when the housing is in the first upper position.

### BRIEF DESCRIPTION OF THE DRAWINGS

FIG. 1 is a plan view illustrating an example of a processing system.

FIG. 2 is a side view illustrating an example of a processing system.

FIG. 3 is a schematic cross-sectional view illustrating an example of a maintenance device.

FIG. 4 is a flowchart illustrating an example of a maintenance method.

FIG. 5 is a view illustrating an example of a maintenance sequence in a first embodiment.

FIG. 6 is an enlarged cross-sectional view illustrating an example of a lock mechanism.

FIG. 7 is an enlarged cross-sectional view illustrating an example of connection of an electrical system of a transfer robot and connection of a VTM and a gas system of a maintenance device.

FIG. 8 is a view illustrating an example of a maintenance sequence in the first embodiment.

FIG. 9 is an enlarged cross-sectional view illustrating an example of connection of an electrical system of a transfer robot and connection of a VTM and a gas system of a maintenance device.

FIG. 10 is a view illustrating an example of a maintenance sequence in the first embodiment.

FIG. 11 is a view illustrating an example of a structure of a support unit.

FIG. 12 is an enlarged cross-sectional view illustrating an example of a lock mechanism.

FIG. 13 is an enlarged cross-sectional view illustrating an example of connection of an electrical system of a transfer robot and connection of a VTM and a gas system of a maintenance device.

FIG. 14 is a view illustrating an example of a maintenance sequence in the first embodiment.

FIG. 15 is an enlarged cross-sectional view illustrating an example of connection of an electrical system of a transfer robot and connection of a VTM and a gas system of a maintenance device.

FIG. 16 is a view illustrating an example of a maintenance sequence in the first embodiment.

FIG. 17 is a view illustrating an example of a maintenance sequence in the first embodiment.

FIG. 18 is a view illustrating an example of a maintenance sequence in a second embodiment.

FIG. 19 is a view illustrating an example of a maintenance sequence in the second embodiment.

FIG. 20 is a view illustrating an example of a maintenance sequence in the second embodiment.

FIG. 21 is a view illustrating an example of a maintenance sequence in the second embodiment.

FIG. 22 is a view illustrating an example of a maintenance sequence in the second embodiment.

FIG. 23 is a view illustrating an example of a maintenance sequence in the second embodiment.

FIG. 24 is a view illustrating an example of a maintenance sequence in the second embodiment.

FIG. 25 is a view illustrating an example of a maintenance sequence in a third embodiment.

FIG. 26 is a view illustrating an example of a maintenance sequence in the third embodiment.

FIG. 27 is a view illustrating an example of a maintenance sequence in a fourth embodiment.

FIG. 28 is a view illustrating an example of a maintenance sequence in a fifth embodiment.

FIG. 29 is a view illustrating an example of a maintenance sequence in the fifth embodiment.

FIG. 30 is an enlarged cross-sectional view illustrating an example of connection of an EFEM and a gas system of a maintenance device.

FIG. 31 is a view illustrating an example of a maintenance sequence in the fifth embodiment.

FIG. 32 is a view illustrating an example of a maintenance sequence in the fifth embodiment.

FIG. 33 is a view illustrating an example of a maintenance sequence in the fifth embodiment.

FIG. 34 is a view illustrating an example of a maintenance sequence in the fifth embodiment.

FIG. 35 is a view illustrating an example of a maintenance sequence in the fifth embodiment.

FIG. 36 is a view illustrating an example of a maintenance sequence in the sixth embodiment.

FIG. 37 is a view illustrating an example of a maintenance sequence in a sixth embodiment.

FIG. 38 is a view illustrating an example of a maintenance sequence in the sixth embodiment.

FIG. 39 is an enlarged cross-sectional view illustrating an example of connection of an EFEM and a gas system of a maintenance device.

FIG. 40 is a view illustrating an example of a maintenance sequence in the sixth embodiment.

FIG. 41 is a view illustrating an example of a maintenance sequence in the sixth embodiment.

FIG. 42 is a view illustrating an example of a maintenance sequence in the sixth embodiment.

FIG. 43 is a view illustrating another example of a shutter structure.

### DETAILED DESCRIPTION

Hereinafter, an embodiment of a maintenance device will be described in detail based on the drawings. In addition, the disclosed maintenance device is not limited by the embodiment below.

However, during an operation of a transfer module that transfers a substrate under a preset environment, such as a vacuum atmosphere, there are cases in which maintenance of parts, such as a transfer robot, within the transfer module is required. In such a case, if the transfer module is opened to the atmosphere and maintenance of parts is performed, it takes time to return the inside of the transfer module to the original environment after the maintenance of the parts. Therefore, the substrate cannot be transferred until the environment within the transfer module returns to the original environment, and thus, throughput of the substrate processing decreases.

Therefore, the present disclosure provides a technology that may suppress a decrease in throughput entailed in the maintenance of parts within the transfer module.

### First Embodiment

[Configuration of processing system 1]

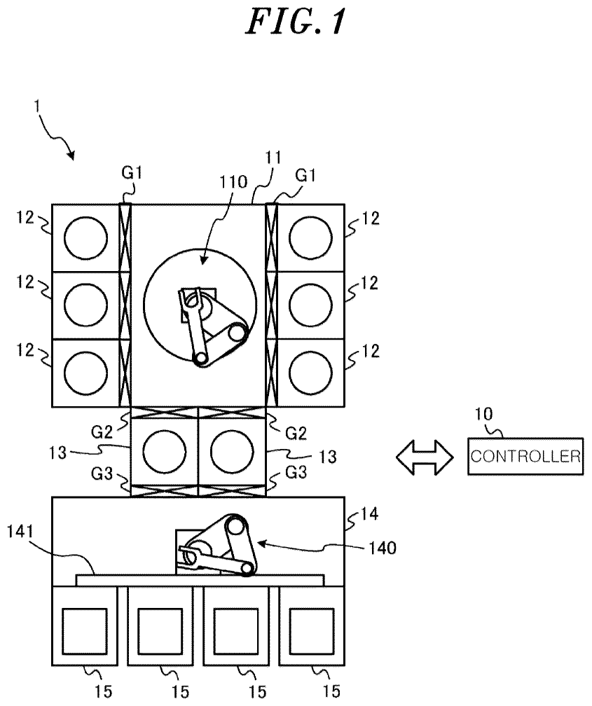

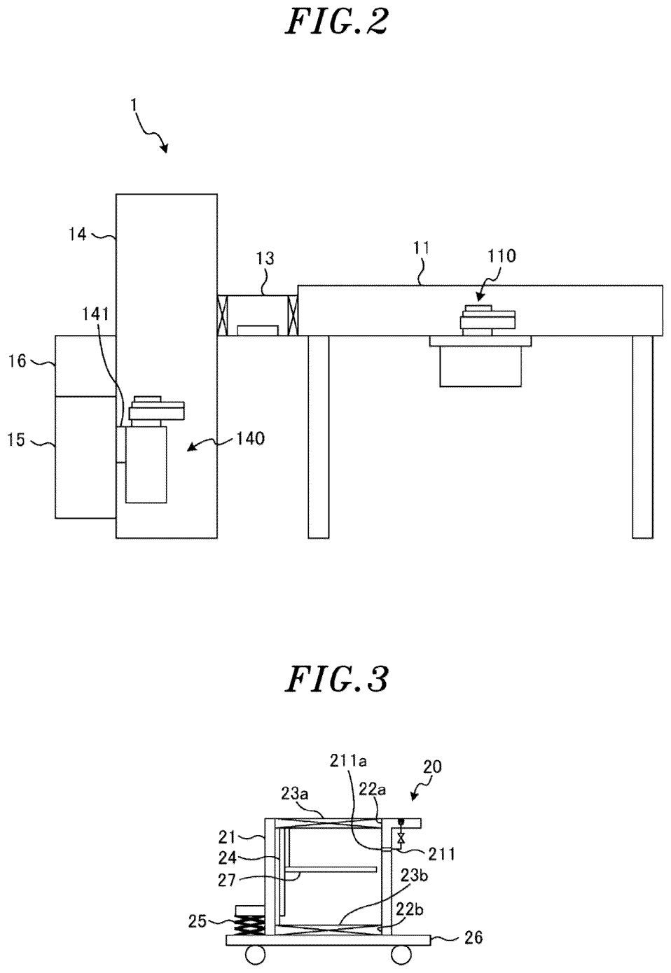

FIG. 1 is a plan view illustrating an example of the configuration of a processing system 1. FIG. 2 is a side view illustrating an example of a processing system 1. In FIGS. 1 and 2, internal components of some devices are shown for convenience.

The processing system 1 includes a vacuum transfer module (VTM) 11, a plurality of process modules (PMs) 12, a plurality of load lock modules (LLMs) 13, and an equipment front end nodule (EFEM) 14. A plurality of PMs 12 are connected to a sidewall of the VTM 11 via a gate valve G1. In addition, in the example of FIG. 1, six PMs 12 are connected to the VTM 11, but the number of PMs 12 connected to the VTM 11 may be more than six or may be less than six. The VTM 11 and the EFEM 14 are examples of transfer modules.

Each PM 12 performs etching or film formation, etc. on the substrate W to be processed. A plurality of LLMs 13 are connected to the other sidewall of the VTM 11, via a gate valve G2. In the example of FIG. 1, two LLMs 13 are connected to the VTM 11, but the number of LLMs 13 connected to the VTM 11 may be more than two and may be one.

A transfer robot 110 is disposed inside the VTM 11. The transfer robot 110 transfers the substrate W between the PM 12 and another PM 12 and between the PM 12 and the LLM 13. The inside of the VTM 11 is maintained at a predetermined pressure atmosphere lower than the atmospheric pressure.

The VTM 11 is connected to one sidewall of each LLM 13 via the gate valve G2, and the EFEM 14 is connected to the other sidewall via a gate valve G3. When the substrate W is loaded into the LLM 13 from the EFEM 14 via the gate valve G3, the gate valve G3 is closed and pressure inside the LLM 13 is lowered to a predetermined pressure. Then, the gate valve G2 is opened and the substrate W inside the LLM 13 is loaded into the VTM 11 by the transfer robot 110.

In addition, while the pressure inside the LLM 13 is lower than the atmospheric pressure, the substrate W is loaded into the LLM 13 from the VTM 11 via the gate valve G2 by the transfer robot 110, and the gate valve G2 is closed. Also, the pressure inside the LLM 13 rises to the same level as that of the pressure inside the EFEM 14. Also, the gate valve G3 is opened, and the substrate W inside the LLM 13 is transferred into the EFEM 14.

A plurality of load ports 15 are provided on a sidewall of the EFEM 14 opposite to the sidewall of the EFEM 14 on which the gate valve G3 is provided. An accommodating container 16, such as a front opening unified pod (FOUP) capable of accommodating a plurality of substrates W is connected to each load port 15. In addition, the EFEM 14 may be provided with an aligner module or the like that changes the direction of the substrate W. In addition, an accommodating container capable of accommodating a consumable part, such as an edge ring (ER), is connected to one of the plurality of load ports 15.

The inside of the EFEM 14 is filled with a gas having a predetermined pressure. In the present embodiment, the predetermined pressure is, for example, atmospheric pressure. In addition, in the present embodiment, the gas filling the inside of the EFEM 14 is, for example, an inert gas, such as nitrogen gas, and the inert gas circulates in the EFEM 14. A transfer robot 140 is provided in the EFEM 14. The transfer robot 140 moves in the EFEM 14 along a guide rail 141 provided on the sidewall of the EFEM 14 and transfers the substrate W between the LLM 13 and the accommodating container connected to the load port 15. A fan filter unit (FFU) or the like is provided in an upper portion of the EFEM 14, and an inert gas from which particles, etc. have been removed is supplied into the EFEM 14 from the upper part, and a downflow is formed in the EFEM 14. In addition, in the present embodiment, the pressure in the EFEM 14 is atmospheric pressure, but in another form, the pressure in the EFEM 14 may be controlled to be positive pressure. Accordingly, it is possible to suppress the intrusion of particles, etc. from the outside into the EFEM 14.

A controller 10 has a memory, a processor, and an input/output (I/O) interface. Data, such as recipes, and programs, etc. are stored in the memory. The memory is, for example, a random access memory (RAM), a read only memory (ROM), a hard disk drive (HDD), or a solid state drive (SSD). The processor controls each part of the processing system 1 through the I/O interface based on data, such as recipes, stored in the memory by executing a program read from the memory. The processor is a central processing unit (CPU) or a digital signal processor (DSP), etc.

[Configuration of maintenance device 20]

FIG. 3 is a schematic cross-sectional view illustrating an example of the maintenance device 20. The maintenance device 20 illustrated in FIG. 3 is a device used to assist in the exchange of the transfer robot loaded in the VTM 11.

The maintenance device 20 in the present embodiment includes a carriage 26, an accommodating container 21, a jack 25, a shutter 23a, a shutter 23b, a support unit 27, and an arm 24. The accommodating container 21 has an opening 22a and an opening 22b. The opening 22a is an example of an upper opening, and the opening 22b is an example of a lower opening. The accommodating container 21 is disposed above the carriage 26. The jack 25 is mounted on the carriage 26 and is configured to raise and lower the accommodating container 21 between a first upper position and a first lower position. The first upper position and the first lower position will be described below.

The accommodating container 21 is connected to the transfer module when it is in the first upper position. The shutter 23b is configured to open and close the opening 22b. The support unit 27 is configured to support the transfer robot. The arm 24 is configured to raise and lower the support unit 27 between the second upper position within the accommodating container 21 and the second lower position below the accommodating container 21 when the accommodating container 21 is in the first upper position. The second upper position and the second lower position will be described below. A through-hole 211a is formed in the sidewall of the accommodating container 21, and a pipe 211 is connected to the through-hole 211a. In the present embodiment, the accommodating container 21 is an example of a housing, the jack 25 is an example of a first lifting unit, the shutter 23a is an example of an upper shutter, the shutter 23b is an example of a lower shutter, and the arm 24 is an example of a second lifting unit.

[Maintenance method]

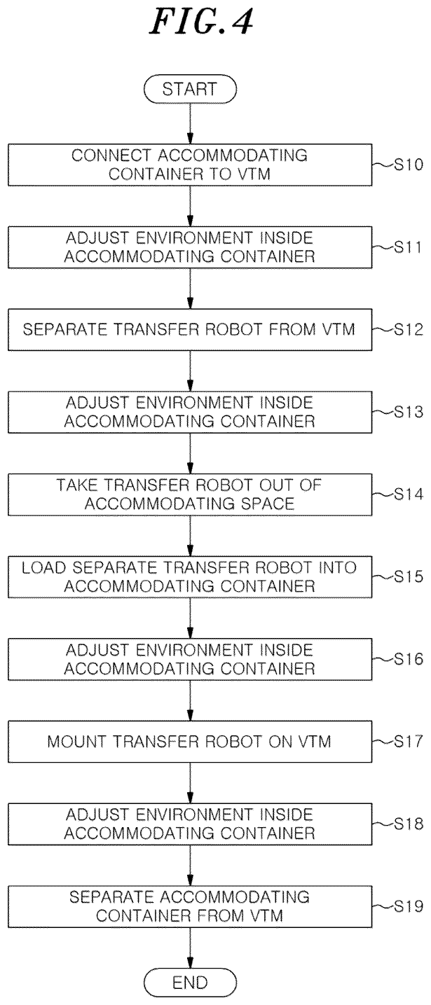

FIG. 4 is a flowchart illustrating an example of a maintenance method. In the maintenance method illustrated in FIG. 4, a work sequence for exchanging the transfer robot 110 mounted on the VTM 11 to assist in the exchanging of the transfer robot 110 is shown.

First, the accommodating container 21 is connected to the VTM 11 (S10). In step S10, as illustrated in FIG. 5, for example, the carriage 26 of the maintenance device 20 moves downward from the VTM 11. The movement of the carriage 26 may be executed by a worker or may be executed by an unillustrated automatic driving mechanism provided in the carriage 26. In addition, hereinafter, hatching is performed in a space having a predetermined pressure atmosphere lower than atmospheric pressure. In the example of FIG. 5, hatching is performed in a space within the VTM 11. The position of the accommodating container 21 for the carriage 26 illustrated in FIG. 5 is an example of the first lower position.

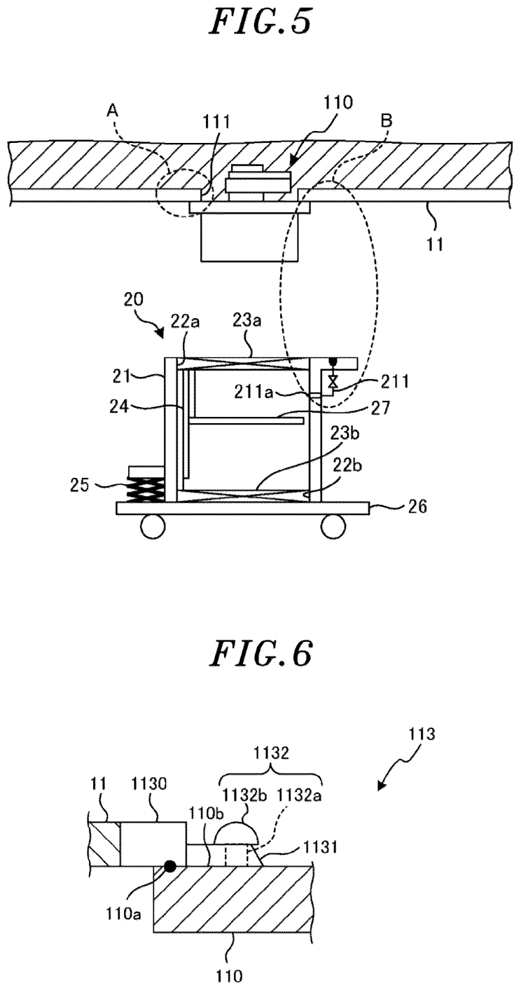

The transfer robot 110 is mounted in an opening 111 formed at the bottom of the VTM 11. An enlarged view of the region A of FIG. 5 is illustrated in FIG. 6. FIG. 6 is an enlarged cross-sectional view illustrating an example of a lock mechanism 113. As illustrated in FIG. 6, the lock mechanism 113 has an actuator 1130 provided at the bottom of the VTM 11 and a wedge-shaped cylinder 1131. In addition, the lock mechanism 113 has a pin 1132 provided on the transfer robot 110. The pin 1132 has a small-diameter portion 1132a provided on an upper surface of a circumferential portion 110b of the transfer robot 110 and a large-diameter portion 1132b provided at the tip of the small-diameter portion 1132a. A sealing member 110a, such as an O-ring, is disposed between the bottom portion of the VTM 11 and the circumferential portion 110b of the transfer robot 110. For example, as shown in FIG. 6, the cylinder 1131 is inserted between the large diameter portion 1132b and the upper surface of the circumferential portion 110b of the transfer robot 110 by an actuator 1130. As a result, the transfer robot 110 is fixed to the bottom portion of the VTM 11 to close the opening 111 of the VTM 11. The driving of the cylinder 1131 by the actuator 1130 is controlled by, for example, the controller 10, etc.

In addition, an enlarged view of region B of FIG. 5 is shown in FIG. 7. FIG. 7 is an enlarged cross-sectional view illustrating an example of connection of an electrical system of the transfer robot 110 and connection of the VTM 11 and a gas system of the maintenance device 20. As shown in FIG. 7, the lock mechanism 113 is also provided in the region B. In addition, the lock mechanism 113 is not limited to the configuration illustrated in FIGS. 6 and 7 and may be configured to secure the VTM 11 and the transfer robot 110 by means of a bolt or screw, etc.

In addition, as illustrated in FIG. 7, the electrical system of the transfer robot 110 is connected to the electrical system of the VTM 11 via a connector 115. In addition, a plug 116a of a joint 116 is provided on a lower surface of the VTM 11, and a valve 117a and a valve 117b are connected to the plug 116a via a pipe 114. A supply source (dry air supply source) of clean dry air (CDA) is connected to the valve 117a, and an exhaust device including a vacuum pump (not illustrated), etc. is connected to the valve 117b.

A socket 116b of a joint 116 is provided on an upper surface of the accommodating container 21, and the pipe 211 is connected to the socket 116b. The pipe 211 communicates with a space inside the accommodating container 21 through the through-hole 211a formed in the sidewall of the accommodating container 21. A valve 210 is provided in the pipe 211. In addition, a sealing member 21a, such as an O-ring, is disposed on the upper surface of the accommodating container 21. In addition, as another example, the valve 210 may not be provided in the pipe 211.

In addition, in the present embodiment, the environment inside the accommodating container 21 is adjusted through the pipe 114 provided in the VTM 11, but the disclosed technology is not limited thereto. The environment inside the accommodating container 21 may be adjusted by a gas supply mechanism and an exhaust mechanism provided separately from the VTM 11. This simplifies the connection between the VTM 11 and the accommodating container 21.

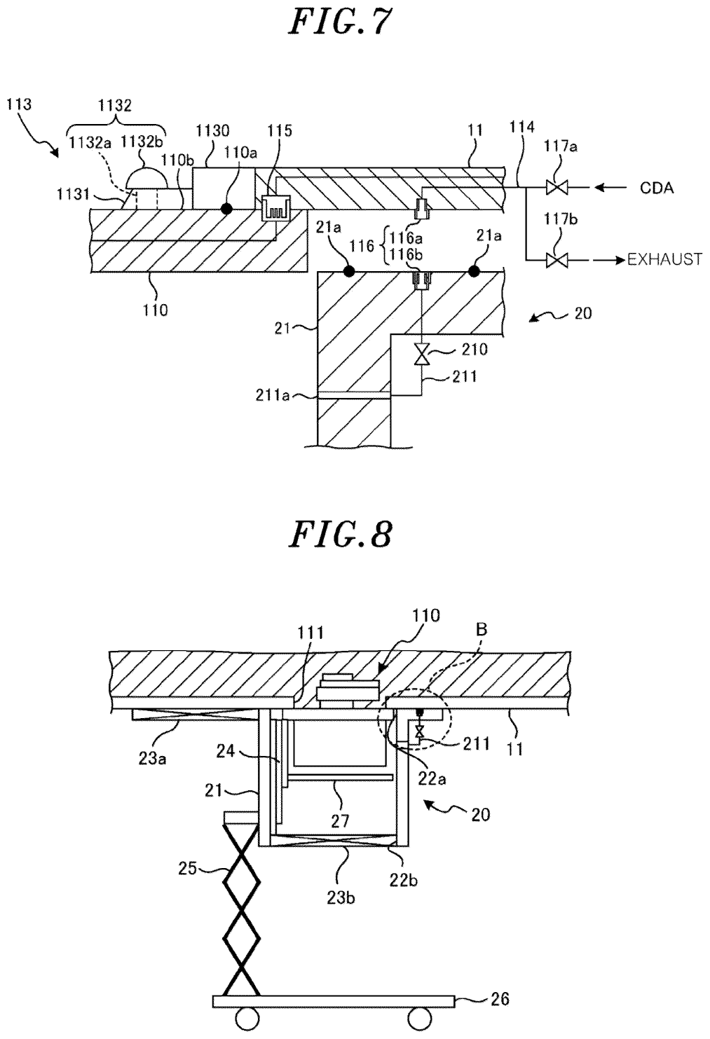

Also, for example, as shown in FIG. 8, the shutter 23a is opened, the accommodating container 21 is lifted by the jack 25, and the accommodating container 21 and the VTM 11 are connected. A position of the accommodating container 21 with respect to the carriage 26 illustrated in FIG. 8 is an example of the first upper position. At this time, in the region B of FIG. 8, as shown in FIG. 9, for example, the lower surface of the VTM 11 and the upper surface of the accommodating container 21 are in contact with each other, and the plug 116a and the socket 116b of the joint 116 are connected. Accordingly, gas inside the accommodating container 21 is discharged through the valve 117b and the pipe 211, and the pressure inside the accommodating container 21 may be close to the pressure inside the VTM 11. In addition, CDA is supplied inside the accommodating container 21 through the valve 117a and the pipe 211, and the pressure inside the accommodating container 21 may be returned to the atmospheric pressure.

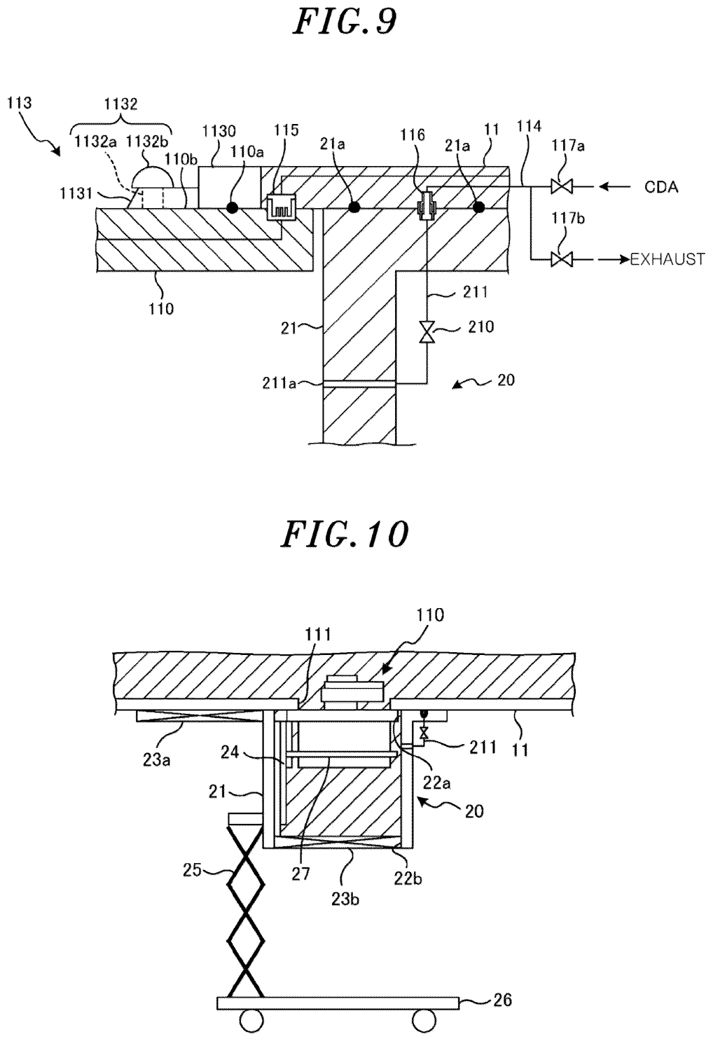

Referring back to FIG. 4, descriptions continue. Next, the environment inside the accommodating container 21 is adjusted (S11). In step S11, the valve 117a is closed, and the valve 117b and the valve 210 are opened, so that the gas inside the accommodating container 21 is discharged through the pipe 211. Then, as shown in FIG. 10, for example, the pressure inside the accommodating container 21 is adjusted so that the pressure inside the accommodating container 21 is equal to the pressure inside the VTM 11. At this time, the shutter 23b is closed. In addition, as a result of adjusting the pressure inside the accommodating container 21, the pressure inside the accommodating container 21 and the pressure inside the VTM 11 do not need to be completely the same pressure, and the pressure inside the accommodating container 21 and the pressure inside the VTM 11 may be somewhat different.

Here, the space within the accommodating container 21 is smaller than the space within the VTM 11. Therefore, the time required to adjust the environment within the accommodating container 21 to be the same as the environment within the VTM 11 is shorter than the time required to return the environment within the VTM 11 to the original environment after the VTM 11 is opened to the atmosphere. Therefore, the time required to exchange the transfer robot 110 may be shortened compared to a case in which the VTM 11 is opened to the atmosphere and the exchange of the transfer robot 110 is executed.

Also, after the environment within the accommodating container 21 is adjusted, the transfer robot 110 is separated from the VTM 11 (S12). In step S12, the transfer robot 110 is supported by the support unit 27, as illustrated in FIG. 10, for example. A position of the support unit 27 with respect to the accommodating container 21 illustrated in FIG. 10 is an example of the second upper position.

The support unit 27 in the present embodiment has an actuator 270 and a grip portion 271, as illustrated in FIG. 11, for example. The actuator 270 is fixed to the arm 24 and drives two grip portions 271. By driving the actuator 270 to reduce a distance between the two grip portions 271, the transfer robot 110 is gripped by the grip portion 271 and the transfer robot 110 is supported by the support unit 27.

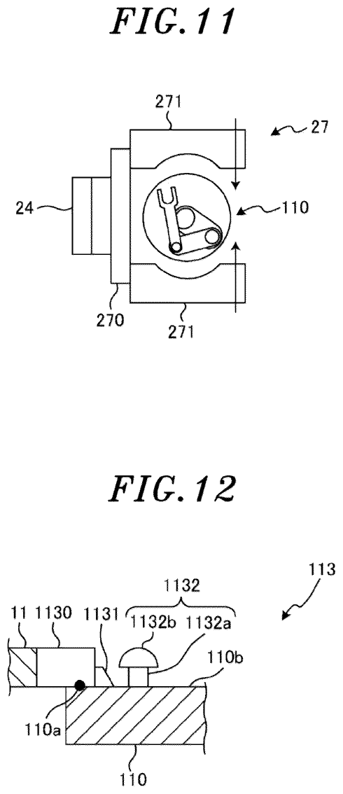

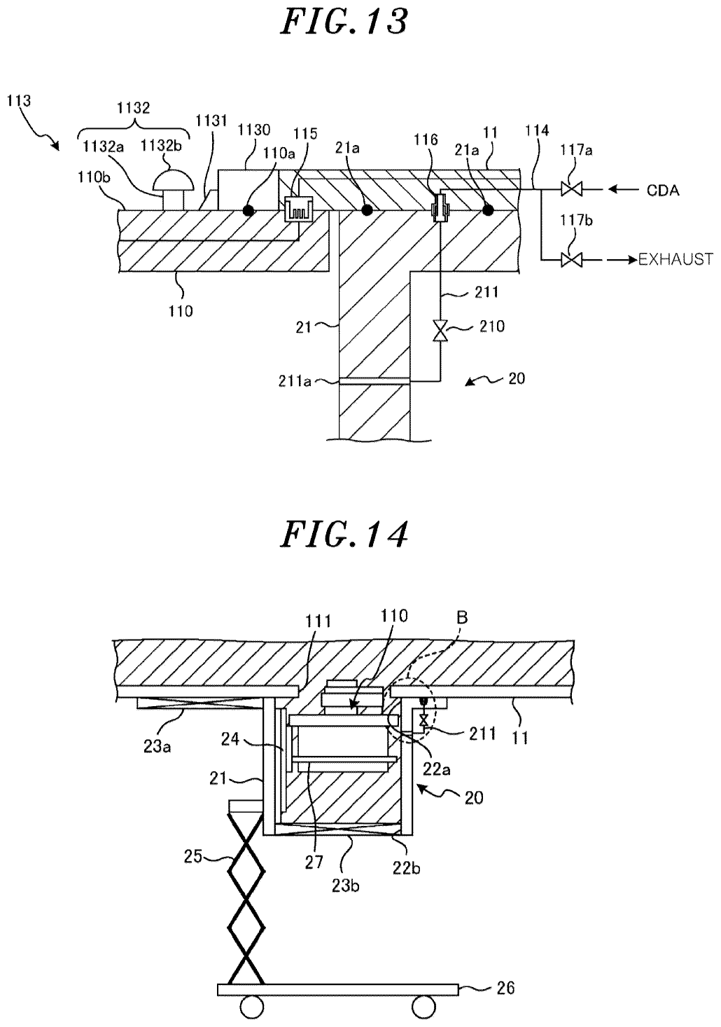

Next, while the transfer robot 110 is supported by the support unit 27, for example, as shown in FIGS. 12 and 13, the cylinder 1131 is retracted from below the large diameter portion 1132b by the actuator 1130. As a result, the lock between the VTM 11 and the transfer robot 110 is released. Then, for example, as shown in FIG. 14, as the arm 24 lowers the support unit 27 supporting the transfer robot 110, the transfer robot 110 is lowered and the transfer robot 110 is separated from the VTM 11.

An enlarged view of the region B of FIG. 14 is shown in FIG. 15. By lowering the transfer robot 110 by the arm 24, connection between a receptacle 115a and a plug 115b of the connector 115 is released and electrical connection between the VTM 11 and the transfer robot 110 is released.

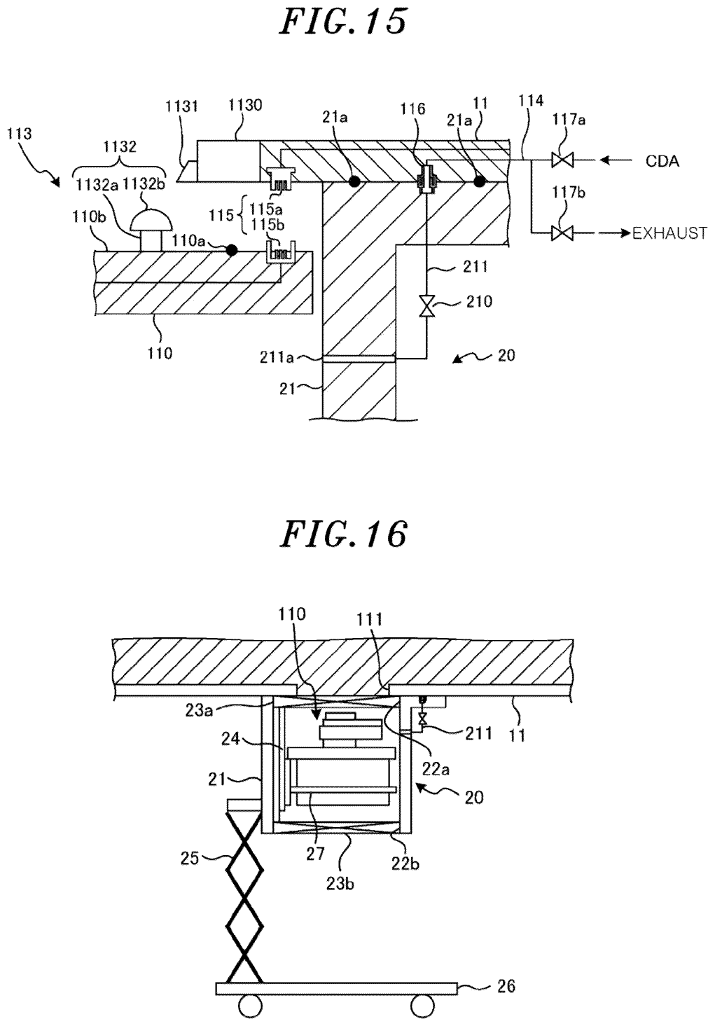

Next, the environment inside the accommodating container 21 is adjusted (S13). In step S13, after the transfer robot 110 is accommodated inside the accommodating container 21, the shutter 23a is closed. Then, the valve 117b is closed, and the valve 117a and the valve 210 are opened, so that the CDA is supplied to the inside of the accommodating container 21 through the pipe 211. As a result, the pressure inside the accommodating container 21 is adjusted so that the pressure inside the accommodating container 21 is close to the atmospheric pressure, as illustrated in FIG. 16, for example.

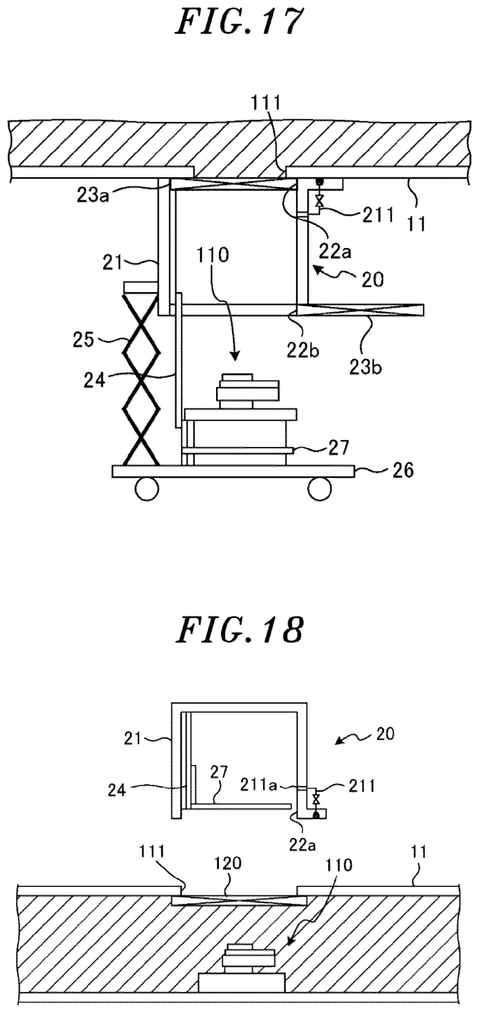

Also, after the pressure inside the accommodating container 21 is adjusted, the transfer robot 110 is taken out of the accommodating container 21 (S14). In step S14, for example, as shown in FIG. 17, the shutter 23b is opened, and the transfer robot 110 is taken out of the accommodating container 21 through the opening 22b by the arm 24. Then, the grip by the support unit 27 is released, and the transfer robot 110 is delivered to a worker, etc. The position of the support unit 27 with respect to the accommodating container 21 illustrated in FIG. 17 is an example of the second lower position.

Next, a separate transfer robot 110 is loaded into the accommodating container 21 (S15). In step S15, for example, as shown in FIG. 17, the separate transfer robot 110 is mounted on the carriage 26 by the worker or the like, and the support unit 27 grips the separate transfer robot 11. Then, the arm 24 raises the support unit 27, so that the separate transfer robot 110 is accommodated in the accommodating container 21, and, for example, as shown in FIG. 16, the shutter 23b is closed.

Next, the environment inside the accommodating container 21 is adjusted (S16). In step S16, the valve 117a is closed, and the valve 117b and the valve 210 are opened, so that the gas inside the accommodating container 21 is discharged through the pipe 211. As a result, the pressure inside the accommodating container 21 is adjusted so that the pressure inside the accommodating container 21 is close to the pressure inside the VTM 11.

Also, after the pressure inside the accommodating container 21 is adjusted, a separate transfer robot 110 is mounted on the VTM 11 (S17). In step S17, the shutter 23a is opened, and, for example, as shown in FIG. 14, the arm 24 raises the transfer robot 110. Also, for example, as shown in FIG. 10, while the upper surface of the circumferential portion 110b of the transfer robot 110 and the lower surface of the VTM 11 are in contact, as shown in FIGS. 6 and 9, a cylinder 1131 is inserted below the large-diameter portion 1132b by the actuator 1130. As a result, the transfer robot 110 is mounted at the bottom of the VTM 11 to close the opening 111 of the VTM 11.

Next, the environment inside the accommodating container 21 is adjusted (S18). In step S18, the valve 117b is closed, and the valve 117a and the valve 210 are opened, so that the CDA is supplied into the accommodating container 21 through the pipe 211. As a result, the pressure inside the accommodating container 21 is adjusted so that the pressure inside the accommodating container 21 is close to the atmospheric pressure, as shown in FIG. 8, for example.

Then, after the pressure inside the accommodating container 21 is adjusted, the accommodating container 21 is separated from the VTM 11 (S19). In step S19, the accommodating container 21 is lowered by the jack 25, and the connection between the accommodating container 21 and the VTM 11 is released, as shown in FIG. 5, for example. Then, the maintenance method shown in this flowchart is terminated.

The first embodiment has been described above. As described above, the maintenance device (maintenance device 20) in the present embodiment is a maintenance device for assisting the exchange of the transfer robot (the transfer robot 110) mounted on the transfer module VTM 11 and includes the carriage (the carriage 26), the housing (the accommodating container 21), the first lifting unit (the jack 25), the lower shutter (the shutter 23b), the support unit (the support unit 27), and the second lifting unit (the arm 24). The housing has an upper opening (the opening 22a) and a lower opening (the opening 22b) and is disposed above the carriage. The first lifting unit is mounted on the carriage and is configured to raise and lower the housing between the first upper position and the first lower position. The housing is connected to the transfer module when it is at the first upper position. The lower shutter is configured to open and close the lower opening. The support unit is configured to support the transfer robot. The second lifting unit is configured to raise and lower the support unit between the second upper position within the housing and the second lower position below the housing when the housing is at the first upper position. As a result, maintenance, such as replacement of parts, disposed within the VTM 11 may be made while maintaining the environment within the VTM 11, and a decrease in throughput entailed in the maintenance of parts within the VTM 11 may be suppressed. In addition, as a result of adjusting the environment within the accommodating container 21 to be the same environment as the environment within the VTM 11, the environment within the accommodating container 21 and the environment within the VTM 11 do not need to be completely the same environment, and the environment within the accommodating container 21 and the environment within the VTM 11 may be somewhat different.

In addition, the maintenance device in the embodiment described above further includes an upper shutter (the shutter 23a) configured to open and close the upper opening.

In addition, in the embodiment described above, the housing has a through-hole 211a, and the internal space of the housing communicates with a dry air supply source through the through-hole.

In addition, in the embodiment described above, the housing has a through-hole, and the internal space of the housing communicates with an exhaust device through the through-hole.

### Second Embodiment

In the first embodiment, the maintenance device 20 is connected to the VTM 11 from below the VTM 11. In this respect, in the present embodiment, a point at which the accommodating container 21 of the maintenance device 20 is connected to the VTM 11 from above the VTM 11 is different from the first embodiment. Hereinafter, the differences from the first embodiment will be mainly described.

In the present embodiment, as illustrated in FIG. 18, for example, the opening 111 is formed in an upper portion of the VTM 11, and the opening 111 is opened and closed by the shutter 120. The accommodating container 21 of the maintenance device 20 in the present embodiment is an accommodating container having a ceiling and an opening 22a at the bottom, and the arm 24 and the support unit 27 are provided in the internal space. The arm 24 is configured to raise and lower the support unit 27 between the first position within the accommodating container 21 and the second position below the accommodating container 21. The first position and the second position will be described below. The through-hole 211a is formed on the sidewall of the accommodating container 21, and the pipe 211 is connected to the through-hole 211a. In the present embodiment, the opening 22a is an example of a lower opening, and the arm 24 is an example of a lifting unit.

In the present embodiment, the maintenance device 20 is transported upward from the VTM 11 by an overhead hoist transport (OHT) and is connected to the VTM 11 from above the VTM 11, as shown in FIG. 19, for example. At this time, similar to the first embodiment described using FIG. 9, the upper surface of the VTM 11 and the lower surface of the accommodating container 21 are in contact, and the plug 116a and the socket 116b of the joint 116 are connected.

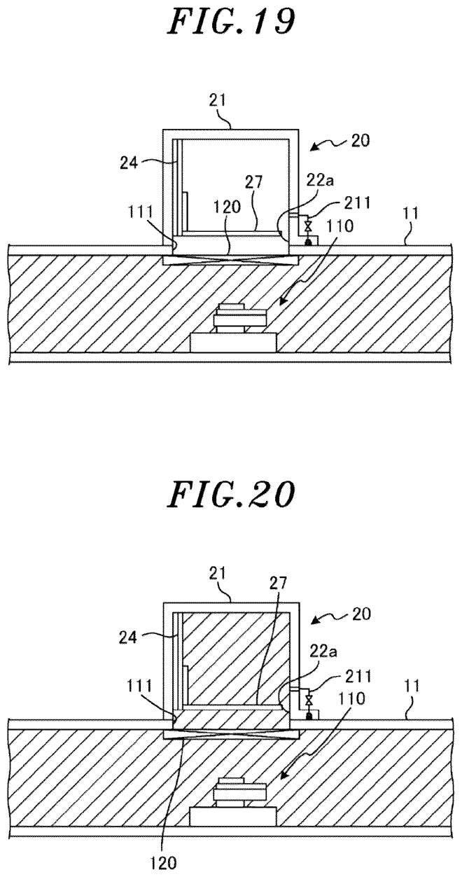

Then, similar to the first embodiment, as the valve 117a is closed and the valve 117b and the valve 210 are opened, the gas in the accommodating container 21 is discharged through the pipe 211. Also, for example, as shown in FIG. 20, the pressure inside the accommodating container 21 is adjusted so that the pressure inside the accommodating container 21 is equal to the pressure inside the VTM 11.

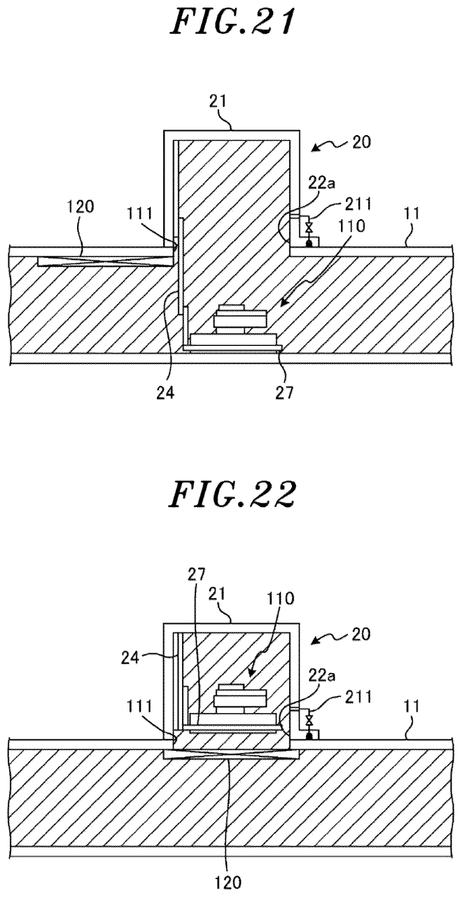

After the pressure inside the accommodating container 21 is adjusted, the shutter 120 of the VTM 11 is opened. Also, for example, as shown in FIG. 21, the arm 24 lowers the support unit 27 through the opening 22a of the accommodating container 21 and the opening 111 of the VTM 11. Also, the support unit 26 enters the VTM 11 and grips the transfer robot 110 installed inside the VTM 11. The position of the support unit 27 with respect to the accommodating container 21 illustrated in FIG. 21 is an example of the second position.

In addition, in the present embodiment, one of the receptacle 115a and the plug 115b of the connector 115 is provided on an upper surface of the bottom portion of the VTM 11. In addition, the other of the receptacle 115a and the plug 115b of the connector 115 is provided on the lower surface of the transfer robot 110. Then, by mounting the transfer robot 110 on the VTM 11 so that the receptacle 115a and the plug 115b fit together, an electrical system of the transfer robot 110 and an electrical system of the VTM 11 are connected via the connector 115.

Next, while the support unit 27 is gripping the transfer robot 110, the arm 24 raises the support unit 27, so that the transfer robot 110 is lifted and the connection between the electrical system of the transfer robot 110 and the electrical system of the VTM 11 is released. Then, as illustrated in FIG. 22, for example, the transfer robot 110 is accommodated in the accommodating container 21 through the opening 22a of the accommodating container 21 and the opening 111 of the VTM 11, and the shutter 120 is closed. The position of the support unit 27 with respect to the accommodating container 21 illustrated in FIG. 22 is an example of the first position.

Next, similarly to the first embodiment, as the valve 117b is opened and the valve 117a and the valve 210 are opened, the CDA is supplied into the accommodating container 21 through the pipe 211. Then, as shown in FIG. 23, for example, the pressure inside the accommodating container 21 is adjusted so that the pressure inside the accommodating container 21 is close to the atmospheric pressure.

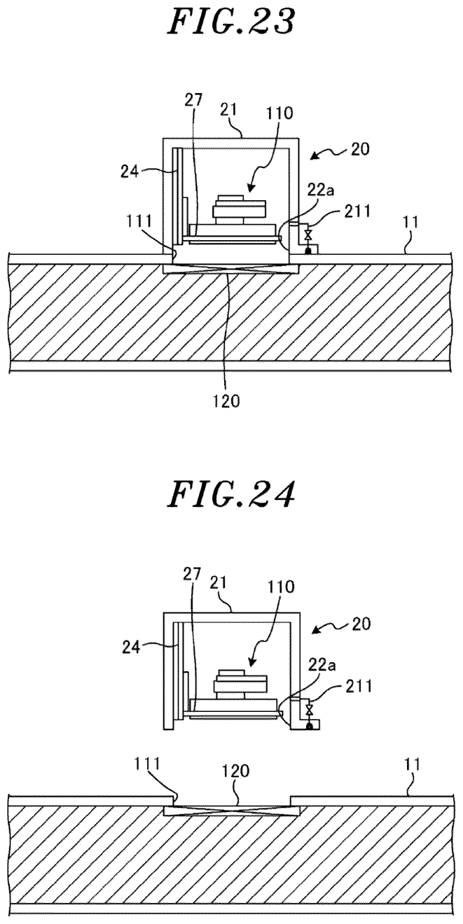

Then, after the pressure inside the accommodating container 21 is adjusted, as shown in FIG. 24, for example, the maintenance device 20 is transported by the OHT or the like together with the transfer robot 110 accommodated inside the accommodating container 21. Then, the transfer robot 110 is taken out from the maintenance device 20 by the worker or the like.

In addition, when a separate transfer robot 110 is mounted, the maintenance device 20 in which the separate transfer robot 110 is accommodated in the accommodating container 21 is transported to an upper side of the VTM 11 by the OHT, etc., as shown in FIG. 24, for example. Then, as shown in FIG. 23, for example, the VTM 11 and the maintenance device 20 are connected, and as shown in FIG. 22, for example, the pressure inside the accommodating container 21 is adjusted so that the pressure inside the accommodating container 21 is close to the pressure inside the VTM 11.

After the pressure inside the accommodating container 21 is adjusted, the shutter 120 of the VTM 11 is opened, and as shown in FIG. 21, for example, the separate transfer robot 110 is installed inside the VTM 11 by the arm 24 and the support unit 27. Also, after the arm 24 is retracted into the accommodating container 21, the shutter 120 of the VTM 11 is closed, as shown in FIG. 20, for example.

Also, as shown in FIG. 19, for example, the pressure inside the accommodating container 21 is adjusted so that the pressure inside the accommodating container 21 is close to the atmospheric pressure. After the pressure inside the accommodating container 21 is adjusted, as shown in FIG. 18, for example, the maintenance device 20 is lifted by the OHT or the like and the connection between the maintenance device 20 and the VTM 11 is released.

The second embodiment has been described above. In the present embodiment, the maintenance device (the maintenance device 20) is a maintenance device for assisting the exchange of the transfer robot (the transfer robot 110) mounted on the transfer module VTM 11 and includes the housing (the accommodating container 21), the support unit (the support unit 27), and the lifting unit (the arm 24). The housing has a lower opening (the opening 22a). The support unit is configured to support the transfer robot. The lifting unit is configured to raise and lower the support unit between the first position within the housing and the second position located below the housing. As a result, maintenance, such as exchange of parts disposed within the VTM 11, is possible while maintaining the environment within the VTM 11, thereby suppressing a decrease in throughput entailed in the maintenance of parts within the VTM 11.

In addition, in the embodiment described above, the housing has the through-hole 211a, and the internal space of the housing communicates with a dry air supply source through the through-hole.

In addition, in the embodiment described above, the housing has a through-hole, and the internal space of the housing communicates with an exhaust device through the through-hole.

### Third Embodiment

The maintenance device 20 in the second embodiment is an accommodating container having a ceiling and the opening 22a at the bottom. In this respect, the accommodating container 21 of the maintenance device 20 in the present embodiment has the opening 22b at the top, the opening 22a at the bottom, and the opening 22b is opened and closed by the shutter 23b, which is different from the second embodiment. Hereinafter, the differences from the second embodiment will be described. In the present embodiment, the opening 22b is an example of an upper opening, the opening 22a is an example of a lower opening, and the shutter 23b is an example of an upper shutter.

In the present embodiment, with the opening 22b closed by the shutter 23b, similarly to the second embodiment, the maintenance device 20 is transported above the VTM 11 by the OHT or the like, and the accommodating container 21 of the maintenance device 20 and the VTM 11 are connected from above the VTM 11. Then, after the pressure inside the accommodating container 21 is adjusted, the shutter 120 is opened and the transfer robot 110 is accommodated in the accommodating container 21 by the arm 24 and the support unit 27. Also, the shutter 120 is closed, and for example, as shown in FIG. 25, the pressure inside the accommodating container 21 is returned to the atmospheric pressure.

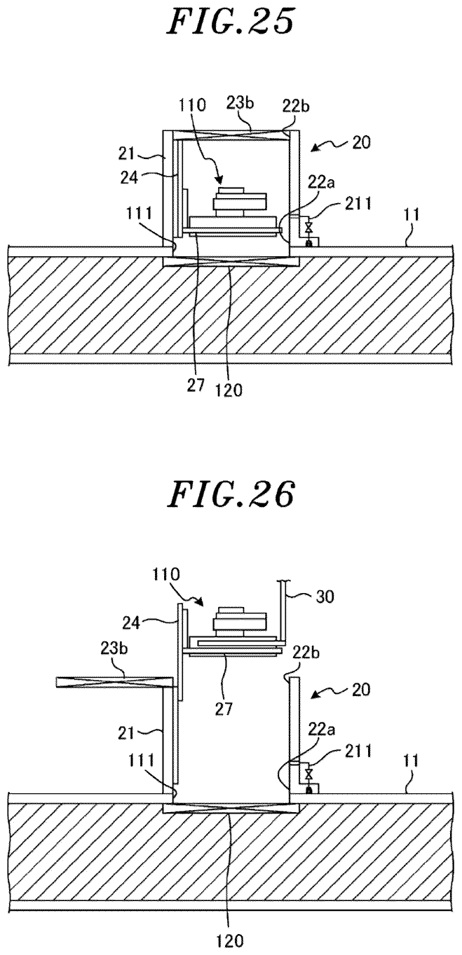

After the pressure inside the accommodating container 21 is returned to the atmospheric pressure, for example, as shown in FIG. 26, the shutter 23b is opened, and the support unit 27 and the transfer robot 110 are lifted upward by the arm 24 more than the opening 22b. Also, the transfer robot 110 is transferred from the support unit 27 to a transfer unit 30, such as the OHT. The position of the support unit 27 with respect to the accommodating container 21 illustrated in FIG. 26 is an example of a third position.

In a case in which a separate transfer robot 110 is mounted, for example, as shown in FIG. 26, the separate transfer robot 110 is transferred from the transfer unit 30, such as the OHT, to the support unit 27. Also, as the support unit 27 is lowered by the arm 24, the transfer robot 110 is accommodated in the accommodating container 21 and the shutter 23b is closed, as shown in FIG. 25, for example. Also, after the pressure inside the accommodating container 21 is adjusted, the shutter 120 is opened and the transfer robot 110 is mounted in the VTM 11 by the arm 24. Also, the arm 24 is retracted into the accommodating container 21, the shutter 120 is closed, and the inside of the accommodating container 21 is adjusted to atmospheric pressure. After the inside of the accommodating container 21 becomes atmospheric pressure, the maintenance device 20 is lifted by the OHT or the like and the connection between the maintenance device 20 and the VTM 11 is released.

The third embodiment has been described. In the present embodiment, the housing (the accommodating container 21) has the upper opening (the opening 22b).

In addition, in the present embodiment, the upper shutter (the shutter 23b) configured to open and close the upper opening is further provided.

In addition, in the present embodiment, the lifting unit (the arm 24) is configured to raise the support unit (the support unit 27) to the third position above the housing (the accommodating container 21).

### Fourth Embodiment

In the third embodiment, the accommodating container 21 and the VTM 11 are connected while the inside of the accommodating container 21 of the maintenance device 20 is at the atmospheric pressure. In this respect, in the present embodiment, the accommodating container 21 and the VTM 11 are connected while the environment inside the accommodating container 21 is maintained at an environment close to the environment inside the VTM 11. Accordingly, after the accommodating container 21 and the VTM 11 are connected, the time required to make the environment inside the accommodating container 21 the same as the environment inside the VTM 11 may be reduced, so that a downtime period of the VTM 11 entailed in the maintenance may be shortened. Hereinafter, differences from the third embodiment will be mainly described.

The maintenance device 20 in the present embodiment has the opening 22b at the top and the opening 22a at the bottom, as shown in FIG. 27, for example, and the opening 22b is opened and closed by the shutter 23b, and the opening 22a is opened and closed by the shutter 23a. In the present embodiment, the opening 22b is an example of an upper opening, the opening 22a is an example of a lower opening, the shutter 23b is an example of an upper shutter, and the shutter 23a is an example of a lower shutter.

In the present embodiment, after the environment inside the accommodating container 21 is adjusted to be the same environment as the environment inside the VTM 11 while the shutter 23a and the shutter 23b are closed, the maintenance device 20 is transported above the VTM 11 by, for example, the OHT or the like, as shown in FIG. 27. Also, from above the VTM 11, the accommodating container 21 of the maintenance device 20 and the VTM 11 are connected, the shutter 23a and the shutter 120 are opened, and the arm 24 is inserted into the VTM 11 through the opening 22a and the opening 111.

Also, the transfer robot 110 is gripped by the support unit 27, and as the support unit 27 is raised by the arm 24, the transfer robot 110 is accommodated in the accommodating container 21. Also, as at least one of the shutter 23a and the shutter 120 is closed, the environment inside the accommodating container 21 is adjusted to be the same environment as the environment outside the accommodating container 21. Also, the shutter 23b is opened, and the support unit 27 and the transfer robot 110 are lifted upward by the arm 24 further than the opening 22b. Also, the transfer robot 110 is transferred from the support unit 27 to the transfer unit 30, such as the OHT.

The fourth embodiment has been described above. The maintenance device (the maintenance device 20) in the present embodiment further includes the lower shutter (the shutter 23a) configured to open and close the lower opening (the opening 22a).

### Fifth Embodiment

In each of the embodiments, the maintenance device 20 is connected to the upper or lower side of the transfer module, but in the present embodiment, the maintenance device 20 is connected to the side of the transfer module. Specifically, in the present embodiment, the maintenance device 20 is connected to a side surface of the EFEM 14. Hereinafter, differences from the first to fourth embodiments will be mainly described.

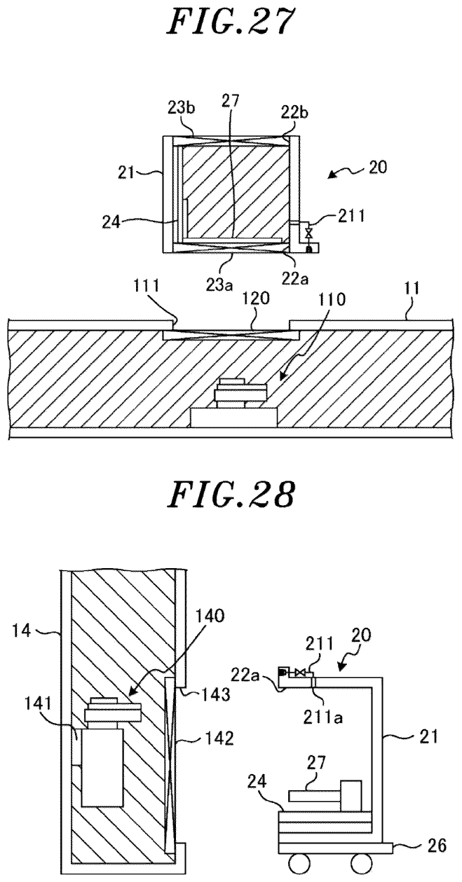

The maintenance device 20 in the present embodiment has, for example, the accommodating container 21 having the opening 22a formed on a side surface thereof, as shown in FIG. 28, and the arm 24 and the support unit 27 are provided inside the accommodating container 21. In addition, the through-hole 211a is formed in the sidewall of the accommodating container 21, and the pipe 211 is connected to the through-hole 211a. In addition, the maintenance device 20 has the carriage 26 for transporting the accommodating container 21.

An opening 143 is formed in a sidewall of the EFEM 14, and the opening 143 is opened and closed by a shutter 142. In the present embodiment, a space inside the EFEM 14 is filled with an inert gas, such as nitrogen gas. Hereinafter, hatching is performed on the space filled with the inert gas.

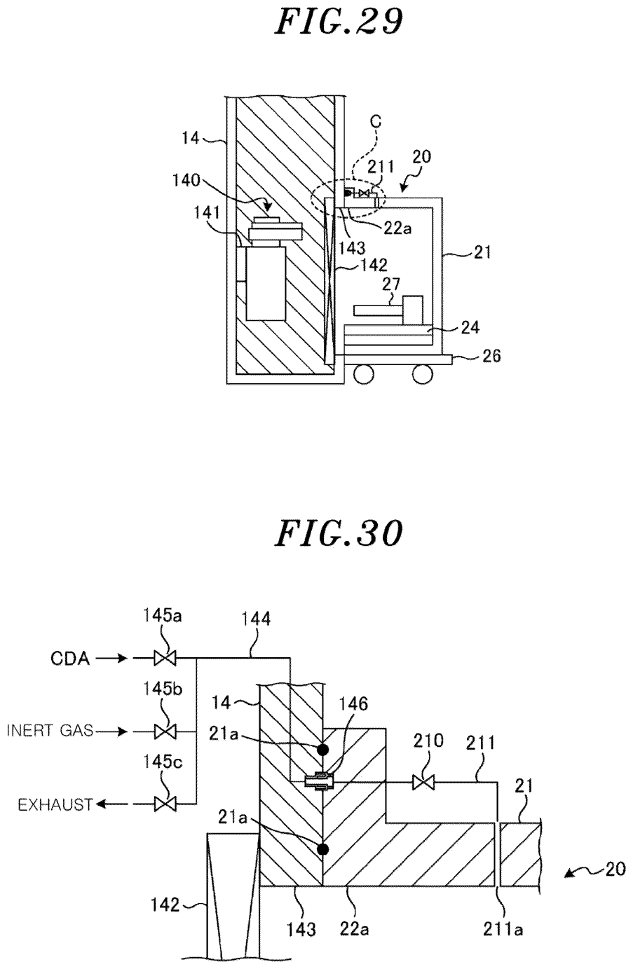

First, by moving the carriage 26 to be close to the EFEM 14, the accommodating container 21 of the maintenance device 20 and the EFEM 14 are connected, for example, as shown in FIG. 29. At this time, in region C of FIG. 29, the side surface of the EFEM 14 and the side surface of the accommodating container 21 are in contact, for example, as shown in FIG. 30 and the plug and socket of the joint 146 are connected. As a result, the valve 145c and the valve 210 are opened, so that the gas inside the accommodating container 21 may be discharged through the pipe 211 and the through-hole 211a. In addition, by opening the valve 145b and the valve 210, the inert gas may be supplied into the accommodating container 21 through the pipe 211 and the through-hole 211a, and the inside of the accommodating container 21 may be filled with the inert gas. In addition, by opening the valve 145a and the valve 210, the CDA may be supplied into the accommodating container 21 through the pipe 211 and the through-hole 211a, so that the environment inside the accommodating container 21 may become close to the environment outside the accommodating container 21.

After the accommodating container 21 and the EFEM 14 are connected, the environment inside the accommodating container 21 is adjusted so that the environment inside the accommodating container 21 becomes the same environment as the environment inside the EFEM 14. For example, the valve 145c and the valve 210 are opened, the gas inside the accommodating container 21 is discharged through the pipe 211 and the through-hole 211a, and thereafter, the valve 145b and the valve 210 are opened and the inert gas is supplied to the inside of the accommodating container 21 through the pipe 211 and the through-hole 211a. After the inside of the accommodating container 21 is filled with the inert gas, the shutter 142 is opened, for example, as shown in FIG. 31.

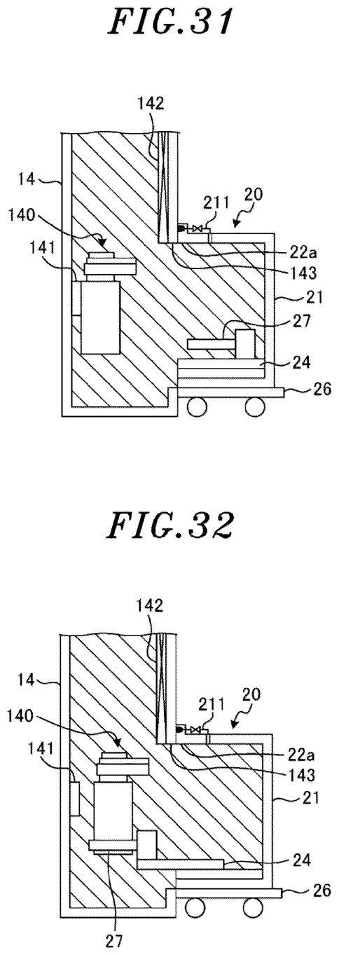

Then, the arm 24 causes the support unit 27 to enter the EFEM 14 through the opening 22a and the opening 143, so that the support unit 27 grips the transfer robot 140. Also, for example, as shown in FIG. 32, by moving the arm 24 away from the guide rail 141, the transfer robot 140 is separated from the guide rail 141.

In addition, the transfer robot 140 and the guide rail 141 are locked by, for example, the same lock mechanism as in the first embodiment. In addition, the transfer robot 140 and the guide rail 141 are electrically connected by, for example, the same connector as in the first embodiment.

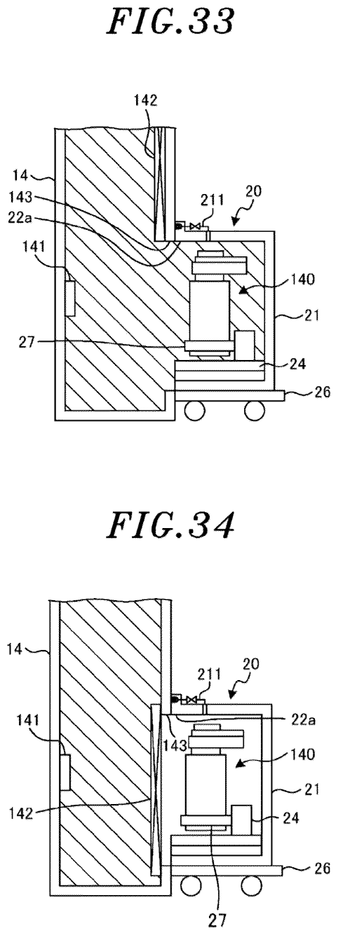

Also, by retracting the arm 24 into the accommodating container 21, the transfer robot 140 is accommodated into the accommodating container 21 through the opening 143 and the opening 22a, as shown in FIG. 33, for example. Then, the shutter 142 is closed, and the environment inside the accommodating container 21 is adjusted so that the environment inside the accommodating container 21 becomes the same as the environment outside the accommodating container 21, as shown in FIG. 34, for example. For example, the valve 145c and the valve 210 are opened, the gas inside the accommodating container 21 is discharged through the pipe 211 and the through-hole 211a, and thereafter, the valve 145a and the valve 210 are opened and the CDA is supplied into the accommodating container 21 through the pipe 211 and the through-hole 211a.

Also, after the accommodating container 21 is filled with the CDA, the connection between the EFEM 14 and the accommodating container 21 is released by moving the carriage 26 away from the EFEM 14, for example, as shown in FIG. 35. As a result, the transfer robot 140 within the EFEM 14 may be separated while maintaining the environment within the EFEM 14.

In addition, when a separate transfer robot 140 is mounted inside the EFEM 14, for example, as shown in FIG. 35, the carriage 26 on which the accommodating container 21 accommodating the separate transfer robot 140 is mounted moves to be close to the EFEM 14. Then, as shown in FIG. 34, for example, the EFEM 14 and the accommodating container 21 are connected. Then, after the accommodating container 21 is filled with an inert gas, as shown in FIG. 33, for example, the shutter 142 is opened, and as shown in FIG. 32, for example, the arm 24 inserts the separate transfer robot 140 into the EFEM 14. Then, the arm 24 mounts the separate transfer robot 140 on the guide rail 141, and the griping of the transfer robot 140 by the support unit 27 is released.

Also, for example, as shown in FIG. 31, after the arm 24 is retracted into the accommodating container 21, the shutter 142 is closed, and the accommodating container 21 is filled with the CDA. After the accommodating container 21 is filled with the CDA, as shown in FIG. 28, for example, the carriage 26 is moved away from the EFEM 14, thereby releasing the connection between the EFEM 14 and the accommodating container 21. As a result, the transfer robot 140 may be mounted inside the EFEM 14 while the environment inside the EFEM 14 is maintained.

The fifth embodiment has been described above. In the present embodiment, the inside of the EFEM 14 is filled with a specific gas different from the atmosphere. In the present embodiment as well, while maintaining the environment inside the EFEM 14, maintenance, such as the exchange of parts disposed inside the EFEM 14 is possible, so that the decrease in throughput entailed in the maintenance of the parts in the EFEM 14 may be suppressed.

### Sixth Embodiment

In each of the embodiments, as parts within the transfer module, the transfer robot provided in the transfer module has been described as an example, but the disclosed technology is not limited thereto. The parts in the transfer module may be any parts other than the transfer robot as long as they are provided in the transfer module and are replaceable parts. The parts other than the transfer robot may include, for example, a load port 15, an aligner module, a wafer storage, various sensors, a gate valve, a lift pin, a stage, etc. The wafer storage is a mechanism provided in the EFEM 14 and temporarily accommodating the substrate W before processing or temporarily accommodating the substrate W after processing. The stage is, for example, a stage on which the substrate W loaded into the LLM 13 is mounted. The lift pin is a mechanism that receives the substrate W from, for example, the transfer robot 110 and the transfer robot 140, is mounted on a stage within the LLM 13, lifts the substrate W from the stage within the LLM 13 and transfers the substrate W to the transfer robot 110 and the transfer robot 140. In the sixth embodiment, the maintenance device 20 that assists in the exchange of the load port 15 within the transfer module is described. Hereinafter, differences from the first to fifth embodiments will be described.

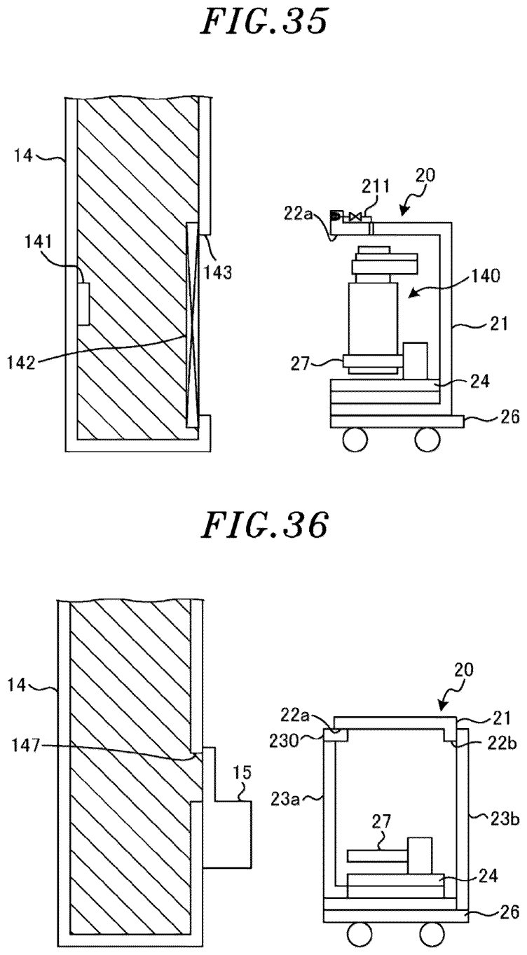

The maintenance device 20 in the present embodiment has the accommodating container 21 having the opening 22a and the opening 22b formed on the side surface thereof, as illustrated in FIG. 36, for example, and the arm 24 and the support unit 27 are provided in the accommodating container 21. The opening 22a is opened and closed by the shutter 23a, and the opening 22b is opened and closed by the shutter 23b. The opening 147 is formed in the sidewall of the EFEM 14, and the load port 15 is provided in the opening 147. In the present embodiment, the space inside the EFEM 14 is filled with an inert gas, such as nitrogen gas. Hereinafter, hatching is performed in the space filled with the inert gas.

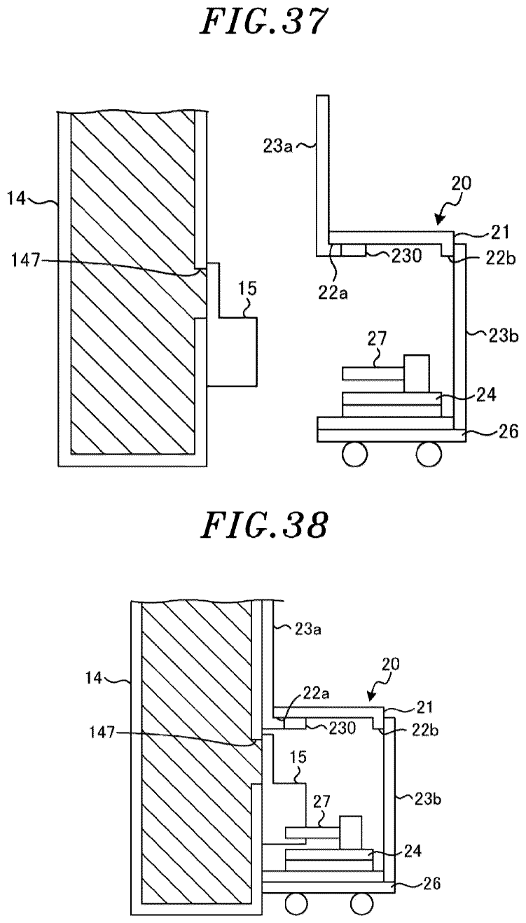

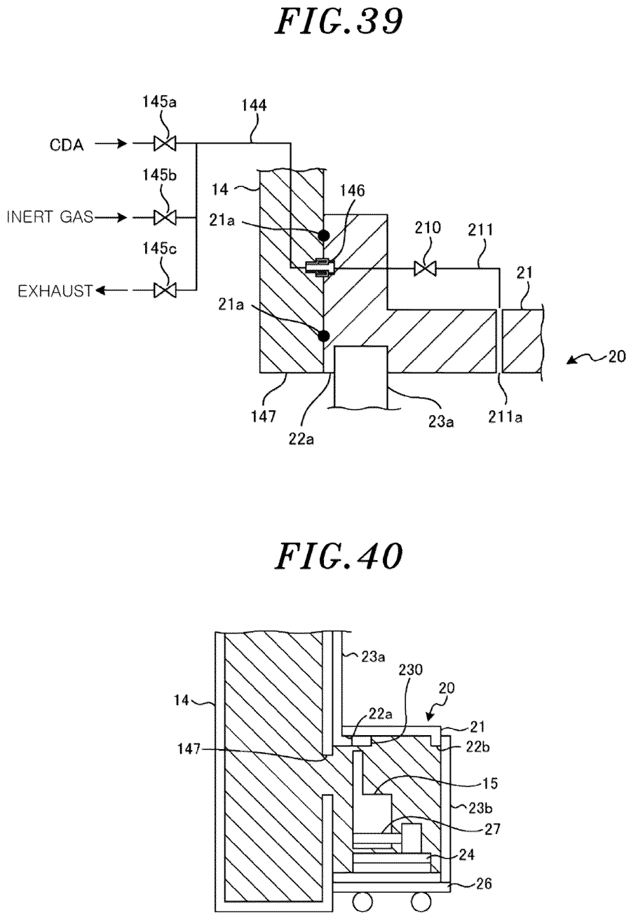

First, as illustrated in FIG. 37, for example, the shutter 230 provided inside the accommodating container 21 is retracted into the inside of the accommodating container 21, and the shutter 23a is opened. Also, by moving the carriage 26 to be close to the EFEM 14, the accommodating container 21 of the maintenance device 20 and the EFEM 14 are connected, for example, as shown in FIG. 38. At this time, the accommodating container 21 and the EFEM 14 are connected, for example, as shown in FIG. 39, with the side surface of the EFEM 14 and the side surface of the accommodating container 21 in contact, so that the plug and socket of the joint 146 are connected. FIG. 39 is a top view of a horizontal cross-section of the accommodating container 21 and the EFEM 14.

Accordingly, the valve 145c and the valve 210 are opened, so that the gas within the accommodating container 21 may be discharged through the pipe 211 and the through-hole 211a. In addition, by opening the valve 145b and the valve 210, the inert gas may be supplied into the accommodating container 21 through the pipe 211 and the through-hole 211a, and the inside of the accommodating container 21 may be filled with the inert gas. In addition, by opening the valve 145a and the valve 210, the CDA may be supplied into the accommodating container 21 through the pipe 211 and the through-hole 211a, so that the environment inside the accommodating container 21 may become close to the environment outside the accommodating container 21.

After the accommodating container 21 and the EFEM 14 are connected, the environment inside the accommodating container 21 is adjusted so that the environment inside the accommodating container 21 becomes the same environment as the environment inside the EFEM 14. For example, the valve 145c and the valve 210 are opened, the gas inside the accommodating container 21 is discharged through the pipe 211 and the through-hole 211a, and thereafter, the valve 145c is closed, the valve 145b is opened, and the inert gas is supplied to the inside of the accommodating container 21 through the pipe 211 and the through-hole 211a.

After the accommodating container 21 is filled with the inert gas, the support unit 27 approaches the load port 15 by the driving of the arm 24 and the support unit 27 grips the load port 15. Then, by moving the support unit 27 away from the EFEM 14 by the driving of the arm 24, the load port 15 is separated from the EFEM 14, for example, as shown in FIG. 40. In addition, the load port 15 and the EFEM 14 are locked by, for example, the same lock mechanism as that in the first and second embodiments. In addition, the load port 15 and the EFEM 14 are electrically connected by, for example, the same connector as that in the first embodiment.

Thereafter, the shutter 23a and the shutter 230 are closed. Also, as shown in FIG. 41, for example, the environment inside the accommodating container 21 is adjusted so that the environment inside the accommodating container 21 becomes the same environment as the environment outside the accommodating container 21. For example, the valve 145c and the valve 210 are opened, the gas inside the accommodating container 21 is discharged through the pipe 211 and the through-hole 211a, and thereafter, the valve 145c is closed, the valve 145a is opened, and the CDA is supplied to the inside of the accommodating container 21 through the pipe 211 and the through-hole 211a.

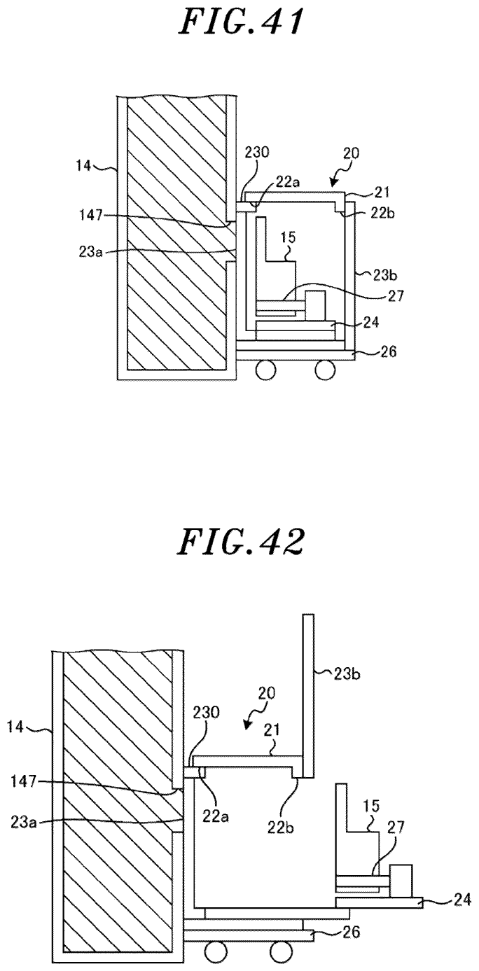

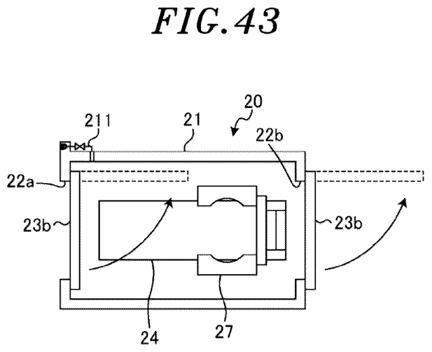

Also, after the accommodating container 21 is filled with the CDA, for example, as shown in FIG. 42, the shutter 23b is opened, and by driving the arm 24, the load port 15 is taken out of the accommodating container 21 through the opening 22b. Accordingly, the load port 15 may be separated from the EFEM 14, while the environment inside the EFEM 14 is maintained.

In addition, in a case in which a separate load port 15 is mounted on the EFEM 14, for example, as shown in FIG. 42, the separate load port 15 is gripped by the support unit 27, and by driving the arm 24, the load port 15 is accommodated inside the accommodating container 21 through the opening 22b. Also, for example, as shown in FIG. 41, the shutter 23b is closed.

Also, after the accommodating container 21 is filled with an inert gas, for example, as shown in FIG. 40, the shutter 230 and the shutter 23a are opened. Also, by driving the arm 24, the load port 15 is mounted on the EFEM 14. Accordingly, the load port 15 may be mounted on the EFEM 14, while the environment within the EFEM 14 is maintained. Also, the grip of the load port 15 by the support unit 27 is released, and by driving the arm 24, the support unit 27 is retracted into the accommodating container 21.

Also, for example, as shown in FIG. 38, the accommodating container 21 is filled with the CDA, and, for example, by moving the carriage 26 away from the EFEM 14, the connection between the EFEM 14 and the accommodating container 21 is released, as shown in FIG. 37, for example.

The sixth embodiment has been described above. In the present embodiment as well, while the environment inside the EFEM 14 is maintained, it is possible to replace parts, such as the load port 15 mounted on the EFEM 14, so that a decrease in throughput entailed in the maintenance of the parts mounted on the EFEM 14 may be suppressed.

In addition, the shutter 23a and the shutter 23b illustrated in FIGS. 36 to 42 are shutters that slide up and down, but the disclosed technology is not limited thereto. As another example, the shutter 23a and the shutter 23b may be shutters that slide in an inclined direction or a lateral direction (for example, a horizontal direction). Alternatively, the shutter 23a and the shutter 23b may be shutters that rotate around a hinge, for example, as shown in FIG. 43. FIG. 43 is a top view of a horizontal cross-section of the maintenance device 20.

### Other Embodiments

In addition, the technology disclosed in the present disclosure is not limited to the embodiment described above and variously modified within the scope of the gist thereof.

For example, in the first to fourth embodiments described above, maintenance of the parts provided within the VTM 11 is performed from below or above the VTM 11, but the disclosed technology is not limited thereto. In another form, for example, similar to the fifth and sixth embodiments, maintenance of the parts provided in the VTM 11 may be performed from the side of the VTM 11.

In addition, in the fifth and sixth embodiments described above, maintenance of the parts provided in the EFEM 14 is performed from the side of the EFEM 14, but the disclosed technology is not limited thereto. In another form, for example, as in the first to fourth embodiments, maintenance of the parts provided in the EFEM 14 may be performed from below or above the EFEM 14.

In addition, in each of the embodiments described above, the exchange of parts of the transfer module is performed by the maintenance device 20, but the disclosed technology is not limited thereto. For example, in the case of an operation related to maintenance of the parts of the transfer module, adjustment or cleaning of the parts may be performed in addition to the exchange of the parts. For example, parts separated from the transfer module by the maintenance device 20 may be re-mounted on the transfer module by the maintenance device 20 after adjustment or cleaning, etc. are performed.

In addition, after the robot arm is provided in the maintenance device 20 and the environment within the maintenance device 20 is adjusted to be the same as the environment within the transfer module, adjustment or cleaning of the parts of the transfer module may be performed by the robot arm. As a result, maintenance, such as adjustment or cleaning, of the parts provided in the transfer module is possible while the environment within the transfer module is maintained. In addition, a maintenance part that performs operations according to the maintenance of the parts of the transfer module may be provided in the accommodating container 21 of the maintenance device 20.

In addition, in each of the embodiments described above, maintenance of the parts provided in the VTM 11 or the EFEM 14 is performed, but the disclosed technology is not limited thereto. In the case of the transfer module that transfers a substrate, the maintenance device 20 may perform maintenance of the parts within the LLM 13.

In addition, in each of the embodiments described above, one transfer robot is provided in each of the VTM 11 and the EFEM 14, but the disclosed technology is not limited thereto. In another form, two or more transfer robots may be provided in the VTM 11 and the EFEM 14. As a result, even if maintenance of some transfer robots is required, the processing of the substrate W may be continued by another transfer robots, thereby avoiding a stoppage of the process.

In addition, it should be considered that the disclosed embodiment is an example and not restrictive in all respects. In fact, the disclosed embodiment may be implemented in various forms. In addition, the disclosed embodiment may be omitted, substituted, or changed in various forms without departing from the scope of the appended claims and their spirit.

In addition, regarding the embodiment described above, the following appendix is disclosed.

### Appendix 1

A maintenance device for assisting an exchange of a transfer robot mounted on a transfer module, the maintenance device comprising:

a carriage;

a housing having an upper opening and a lower opening, wherein the housing is disposed above the carriage;

a first lifting unit mounted on the carriage and configured to raise and lower the housing between a first upper position and a first lower position, wherein the housing is connected to the transfer module when the housing is at the first upper position;

a lower shutter configured to open and close the lower opening;

a support unit configured to support the transfer robot; and

a second lifting unit configured to raise and lower the support unit between a second upper position within the housing and a second lower position below the housing when the housing is at the first upper position.

### Appendix 2

The maintenance device of appendix 1, further comprising an upper shutter configured to open and close the upper opening.

### Appendix 3

The maintenance device of appendix 1 or 2, wherein the housing has a through-hole, and an internal space of the housing communicates with a dry air supply source through the through-hole.

### Appendix 4

The maintenance device of appendices 1 to 3, wherein the housing has a through-hole, and an internal space of the housing communicates with an exhaust device through the through-hole.

### Appendix 5

A maintenance device for assisting an exchange of a transfer robot mounted on a transfer module, the maintenance device comprising:

a housing having a lower opening;

a support unit configured to support the transfer robot; and

a lifting unit configured to raise and lower the support unit between a first position within the housing and a second position below the housing.

### Appendix 6

The maintenance device of appendix 5, further comprising a lower shutter configured to open and close the lower opening.

### Appendix 7

The maintenance device of appendix 5 or 6, wherein the housing has an upper opening.

### Appendix 8

The maintenance device of appendix 7, further comprising an upper shutter configured to open and close the upper opening.

### Appendix 9

The maintenance device of appendix 7 or 8, wherein the lifting unit is configured to raise the support unit to a third position above the housing.

### Appendix 10

The maintenance device of appendices 5 to 9, wherein the housing has a through-hole, and an internal space of the housing communicates with a dry air supply source through the through-hole.

### Appendix 11

The maintenance device of appendices 5 to 9, wherein the housing has a through-hole, and an internal space of the housing communicates with an exhaust device through the through-hole.

### Appendix 12

A maintenance device for assisting an exchange of a transfer robot mounted on a transfer module, the maintenance device comprising:

a housing having an opening;

a shutter configured to open and close the opening;

a support unit configured to support the transfer robot; and

a driving unit configured to move the support unit between a first position within the housing and a second position outside the housing.

### Appendix 13

The maintenance device of appendix 12, wherein the opening is formed in a sidewall of the housing, and the driving unit is configured to move the support unit in a horizontal direction.

### Appendix 14

The maintenance device of appendix 12 or 13, wherein the housing has a through-hole, and an internal space of the housing communicates with a dry air supply source through the through-hole.

### Appendix 15

The maintenance device of appendices 12 to 14, wherein the housing has a through-hole, and an internal space of the housing communicates with an exhaust device through the through-hole.

1. A maintenance device for assisting an exchange of a transfer robot mounted on a transfer module, the maintenance device comprising:
a carriage;
a housing having an upper opening and a lower opening, wherein the housing is disposed above the carriage;
a first lifting unit mounted on the carriage and configured to raise and lower the housing between a first upper position and a first lower position, wherein the housing is connected to the transfer module when the housing is at the first upper position;
a lower shutter configured to open and close the lower opening;
a support unit configured to support the transfer robot; and
a second lifting unit configured to raise and lower the support unit between a second upper position within the housing and a second lower position below the housing when the housing is at the first upper position.

2. The maintenance device of claim 1, further comprising an upper shutter configured to open and close the upper opening.

3. The maintenance device of claim 1, wherein the housing has a through-hole, and an internal space of the housing communicates with a dry air supply source through the through-hole.

4. The maintenance device of claim 2, wherein the housing has a through-hole, and an internal space of the housing communicates with a dry air supply source through the through-hole.

5. The maintenance device of claim 1, wherein the housing has a through-hole, and an internal space of the housing communicates with an exhaust device through the through-hole.

6. The maintenance device of claim 2, wherein the housing has a through-hole, and an internal space of the housing communicates with an exhaust device through the through-hole.

7. A maintenance device for assisting an exchange of a transfer robot mounted on a transfer module, the maintenance device comprising:
a housing having a lower opening;
a support unit configured to support the transfer robot; and
a lifting unit configured to raise and lower the support unit between a first position within the housing and a second position below the housing.

8. The maintenance device of claim 7, further comprising a lower shutter configured to open and close the lower opening.

9. The maintenance device of claim 7, wherein the housing has an upper opening.

10. The maintenance device of claim 9, further comprising an upper shutter configured to open and close the upper opening.

11. The maintenance device of claim 10, wherein the lifting unit is configured to raise the support unit to a third position above the housing.

12. The maintenance device of claim 7, wherein the housing has a through-hole, and an internal space of the housing communicates with a dry air supply source through the through-hole.

13. The maintenance device of claim 8, wherein the housing has a through-hole, and an internal space of the housing communicates with a dry air supply source through the through-hole.

14. The maintenance device of claim 7, wherein the housing has a through-hole, and an internal space of the housing communicates with an exhaust device through the through-hole.

15. The maintenance device of claim 8, wherein the housing has a through-hole, and an internal space of the housing communicates with an exhaust device through the through-hole.

16. A maintenance device for assisting an exchange of a transfer robot mounted on a transfer module, the maintenance device comprising:
a housing having an opening;
a shutter configured to open and close the opening;
a support unit configured to support the transfer robot; and
a driving unit configured to move the support unit between a first position within the housing and a second position outside the housing.

17. The maintenance device of claim 16, wherein the opening is formed in a sidewall of the housing, and the driving unit is configured to move the support unit in a horizontal direction.

18. The maintenance device of claim 16, wherein the housing has a through-hole, and an internal space of the housing communicates with a dry air supply source through the through-hole.

19. The maintenance device of claim 17, wherein the housing has a through-hole, and an internal space of the housing communicates with a dry air supply source through the through-hole.

20. The maintenance device of claim 16, wherein the housing has a through-hole, and an internal space of the housing communicates with an exhaust device through the through-hole.
